(19) United States
(12) Patent Application Publication
(10) Pub. No.: US 2005/0184078 A1
(43) Pub. Date: Aug. 25, 2005

(54) Drinking container with article holding clip

(76) Inventor: Daniel Oas, Irwindale, CA (US)

Correspondence Address: THE SONI LAW FIRM, 55 S. LAKE AVE SUITE 720, PASADENA, CA, 91101, US

(21) Appl. No.: 10/783,183

(22) Filed: Feb. 19, 2004

(51) Int. Cl. G11C 11/34

(52) U.S. Cl. 220/756

(57) ABSTRACT

A drinking container with an article holding clip is described. The clip is useful for attaching various objects to a drinking container, for example free coffee drink punch cards, business cards, cash, or even keys. Furthermore, by positioning the clip under a coffee mug handle, the attached objects are less likely to become dislodged accidentally. The present invention further relates to a method of efficiently and inexpensively incorporating a clip into the plastic components of a drinking container, by providing a plastic unitary construction including a liner, a rim, a handle, and the clip for connection with a stainless steel mug body.

### BACKGROUND OF THE INVENTION

1. Field of the Invention

The present invention relates to a drinking container, for example a coffee mug, with a clip. More specifically, the present invention relates to a travel mug with a clip incorporated into and under a mug handle. The clip is useful in attaching various objects to the coffee mug, for example free coffee drink punch cards, business cards, cash, or even keys. The present invention further relates to a method of incorporating a clip into the plastic components of a drinking container, by providing a plastic unitary construction including a liner, a rim, a handle, and the clip for connection with a stainless steel mug body.

2. Description of the Prior Art

Clips have most commonly been placed on various objects in order to attach the object to a pocket or a belt. These clips are designed to free up the user's hands and to secure the object for convenient use. Examples of objects frequently including a clip are phones, pagers, and tools. Other types of clips are used to hold an article. Perhaps the best known example of this is a clip on a clipboard. Furthermore, clips have been described in the prior art on containers. The usual configuration of these clips is to function as a means of attaching the container to the user's belt.

U.S. Pat. No. 6,273,283 to Terrana et al. describes a cylindrical plastic beverage bottle with an integral clip formed in the side of the container. The clip is designed to allow the user to attach the bottle to a support structure. However, the size and character of this clip will not allow the clip to grasp thin objects such as a card.

U.S. Pat. No. 5,439,125 to Bloch briefly mentions a simple clip on the side on the side of a drinking container for use in attaching the container to a belt.

U.S. Pat. No. 5,743,620 to Rojas et al. discloses an illuminated drinking receptacle designed to be suspended from a belt. The clip structure is bulky and the structure of the clip is not designed to hold paper, cards, nor keys.

U.S. Pat. No. 5,609,277 to McDonald describes a holder for enclosing and supporting a beverage can residing within an insulating sleeve. The holder includes a handle and a clip for attachment to a belt.

At least one patent describes use of a clip to attach articles to a beverage container. U.S. Pat. No. 5,960,973 to Markson discloses a beverage container with a clip to hold articles, more specifically snack packages. The Markson first embodiment is designed to slip over the narrow neck of a beverage container. This article carrier would not fit over a mug, nor could the user secure this configuration of clip to a travel mug. Another embodiment of Markson's device attaches to a beverage can. That embodiment could not be securely attached to a tapered mug such as a coffee travel mug. The last Markson embodiment is designed to be placed around a tapered cup. However, the Markson devices are separate attachable clips that are designed for light or temporary use, for example as a promotional display in a store. The devices do not appear to be sturdy enough for repeated daily usage. The Markson article carriers are not well secured to the container and are subject to dislodgement with loss of an attached article. Furthermore, Markson's devices have the disadvantage of being unattractive and intrusive to the placement of a drinking container within a vehicle cup holder.

### SUMMARY OF THE INVENTION

It is accordingly an object of the present invention to provide a clip for a drinking container that will securely hold various articles, especially thin articles, for example paper or a card.

Another object of the present invention is to provide a coffee mug incorporating such a clip in order to attach a free drink card, business cards, advertising, or even a key ring to the mug.

Still another object of this invention is to provide an article holding clip that is integrally incorporated into an unitary construction comprising the plastic components of a drinking container, for example, into the handle of a travel mug.

It is yet another object of the present invention to provide an article holding clip that is located under the handle of a travel mug, such that the article being held is in a protected and secured location upon the mug, under the mug handle.

The objects of this invention are accomplished by an article holding clip mounted on a drinking container. The clip of the present invention is biased against the wall of the drinking container. In the preferred embodiment, the clip is mounted to the underside of the mug handle and is biased against the outside wall of a coffee travel mug. Other objects of this invention are accomplished by incorporating a clip into a unitary construction for use in a drinking container.

The advantage of mounting a clip under the handle is that in a metal mug with a plastic handle, it would be inexpensive and easy to add a biased article holding clip to the underside of the handle during production. The clip would simply be incorporated into the injection molding of the mug's plastic handle. By integrating the clip to the underside of the handle, the clip is very inexpensive to produce and makes a nice extra addition to a travel mug.

The advantage of a unitary construction including a clip is that it would be inexpensive to add a clip to drinking containers which have injection molded plastic handles or a one piece injection molded plastic liner with a plastic rim and a plastic handle. Furthermore, incorporating a clip into an injection molded mug's plastic liner-rim-handle would make it especially easy to add a firmly grasping article holding clip to a metal drinking container, for example a stainless steel type of travel mug. Travel mugs are commonly made of a stainless steel body with a plastic injection molded handle, rim, and lid. Often there is also an insulated plastic liner associated with travel mugs with stainless steel exteriors. The clip of the present invention may be injection molded as an integral part of the handle or as part of a plastic liner-rim-handle-clip unitary construction. Since the clip is incorporated into the molded plastic components, and is biased against the outside metal body of a coffee travel mug, it is simple and inexpensive to add a clip to a travel mug with a metal body. This is in contrast to the cost and extra assembly steps involved in direct attachment of a clip to the stainless steel wall of a travel mug. The plastic injection molded components could simply be connected with the stainless steel outer shell.

Yet another advantage of the article holding clip of the present invention is that various thicknesses of articles can be held by the clip. For example, the clip will accommodate papers, coupons, cards, advertising, cash, and key rings.

In the preferred embodiment of the present invention, the article holding clip of the present invention is part of a unitary construction for use with a drinking container comprising a clip connected underneath, and integrated into, a drinking container handle wherein when said handle is connected with a drinking container body, the clip is biased against the body. The present invention also includes a method of assembling a drinking container including an article holding clip comprising injection molding a unitary construction including a liner, a rim, a handle, and a clip, and connecting the unitary construction with a drinking container body.

Still other objects and advantages of the present invention will become readily apparent to those skilled in the art from the following detailed description, wherein only the preferred embodiment of the invention is shown and described, simply by way of illustration of the best mode contemplated of carrying out the invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

The accompanying Figures depict embodiments of the present invention, and features and components thereof. Unless specifically otherwise disclosed or taught, materials for making components of the present invention are selected from appropriate materials such as metal, metallic alloys, natural or synthetic fibers, plastics and the like, and appropriate manufacturing or production methods including casting, extruding, molding and machining may be used.

Any references to front and back, right and left, top and bottom, superior and inferior, upper and lower, inner and outer, medial and lateral, and horizontal and vertical are intended for convenience of description, not to limit the present invention or its components to any one positional or spacial orientation.

The foregoing objects, features, advantages and preferred embodiments of the present invention will be better understood from the following detailed description taken in conjunction with the accompanying drawings in which:

FIG. 1 illustrates a left side perspective view of an embodiment of the present invention, with a lid attached, showing an article attaching clip connected with the underside of a travel mug handle;

FIG. 2 is a bottom front left side perspective view of the embodiment of the present invention that is shown in FIG. 1, further illustrating a card positioned under the clip. The card is not considered a part of the present invention and is shown by example only.

FIG. 3 is a top front left side perspective view of the embodiment of the present invention that is shown in FIG. 2;

FIG. 4 is a sagittal cross section view of the embodiment of the present invention that is shown in FIG. 3; and;

FIG. 5 is an exploded view illustrating the method of assembly of the preferred embodiment of the present invention.

### DETAILED DESCRIPTION OF THE PREFERRED EMBODIMENTS

The accompanying Figures depict embodiments of the present invention, and features and components thereof. With regard to means for fastening, mounting, attaching or connecting the components of the present invention to form the apparatus as a whole, unless specifically described otherwise, such means are intended to at least encompass conventional fasteners such as machine screws, machine threads, snap rings, hose clamps such as screw clamps and the like, rivets, nuts and bolts, toggles, pins and the like. Components may also be connected by friction fitting, snap fitting, adhesives, or by welding or deformation, if appropriate. Unless specifically otherwise disclosed or taught, materials for making components of the present invention are selected from appropriate materials such as metal, metallic alloys, natural or synthetic fibers, plastics and the like, and appropriate manufacturing or production methods including casting, extruding, molding and machining may be used.

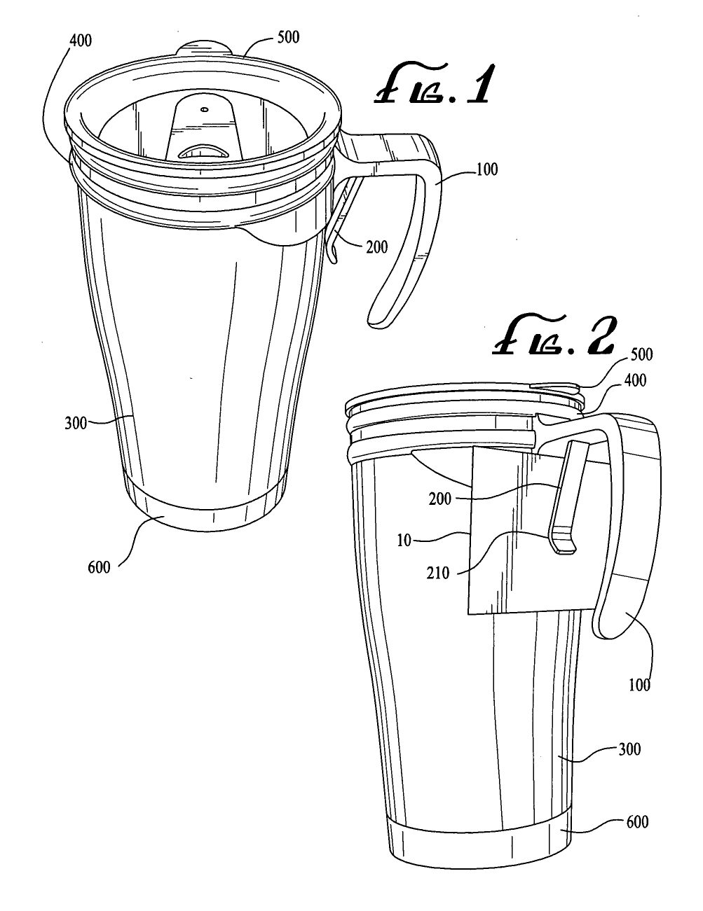

Referring more specifically to the drawings, there is shown in FIG. 1 an embodiment of the present invention of a drinking container with an article holding clip embodying the features of the present invention. Although the preferred embodiment illustrated is a coffee mug, alternative embodiments may be other types of drinking containers, and the example of a travel mug is not meant to be limiting to the present invention. As illustrated, the mug comprises a handle 100, a clip 200, a mug body 300, and a mug rim 400. Optionally, a detachable mug lid 500 may be added to the mug, the lid 500 capable of detachably connecting to the mug rim 400. This type of mug lid 500 is well known in the art, and will not be described further. In some embodiments, a mug base 600 may be attached to the bottom of the mug body 300. This type of travel mug base 600 is also well known in the art.

In the preferred embodiment, the mug body 300 is comprised of metal, for example stainless steel. However, in other embodiments, the mug body 300 could be plastic, ceramic, glass, or other materials commonly in use for drinking containers and mugs. In the preferred embodiment, the handle 100, the clip 200, and the mug rim 400 are comprised of plastic, but other appropriate materials known in the art may be substituted.

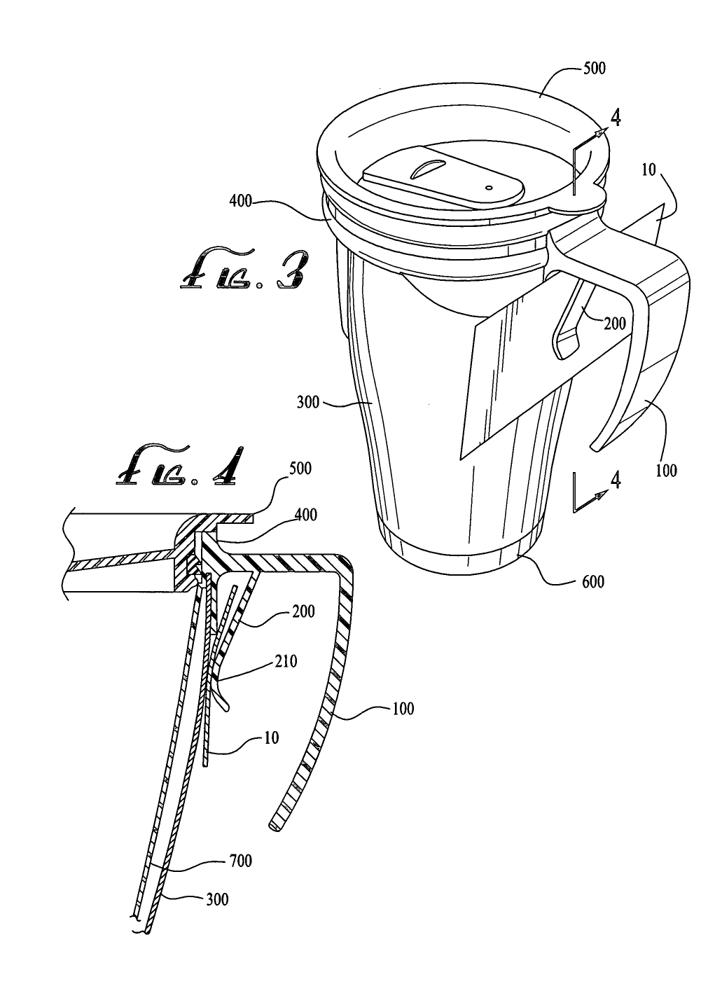

Referring now to FIG. 2 and FIG. 3, in the preferred embodiment, the clip 200 is illustrated connected with the underside of the handle 100. The distal end of the clip 200 is biased against the mug body 300. The biasing force is adequately supplied by the intrinsic resilience of the materials used in manufacture of the clip 200 and handle 100, combined with the angulation of the clip 200 towards the mug body 300. Alternative, a spring may be utilized in other embodiments to provide the biasing force. The clip 200 has a slight bend 210 in its distal portion, angling away from the mug body 300. This bend facilitates sliding an article, illustrated in FIG. 2 as a card 10, between the clip 200 and the mug body 300. The clip 200 may be utilized to hold a card 10, for example a free coffee drink customer card. This type of drink card, not part of the invention itself, is well known and used to reward a free coffee drink to a frequent customer. The clip 200 could also be used to removably attach, for example, a business card, advertising materials, sweetener packages, or even keys to the mug. The clip 200 securely, but removably, holds the article. Furthermore, the position of the article holding clip 200 under the handle 100, in the preferred embodiment, helps protect the secured article from being accidently dislodged by bumps against the mug.

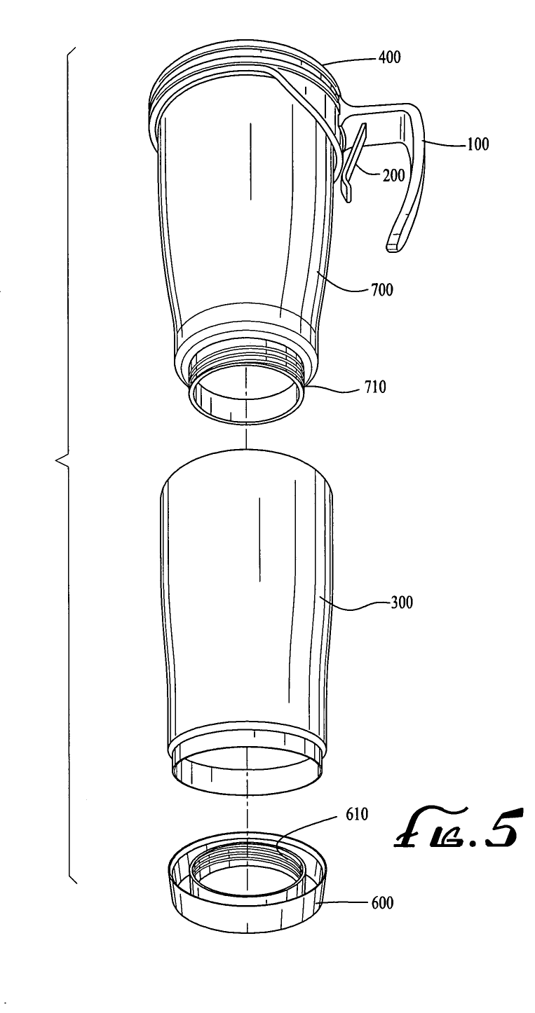

Referring now also to the cross sectional view in FIG. 4, a unitary construction including the handle 100, the clip 200, and the rim 400 are illustrated. In this preferred embodiment, a mug liner 700 is also included in the unitary construction. The liner 700-rim 400-handle 100-clip 200 unitary construction is preferably made of plastic and inexpensively injection molded as one piece, which can then integrated into and connected with the mug body 300, which for example may be manufactured from stainless steel as a separate piece. An air space between the liner 700 and the mug body 300 acts as insulation, helping to keep the drink at a constant temperature.

One advantage of such a unitary construction, including a clip, is that it would be inexpensive to add a clip to present mugs which have injection molded plastic handles. A clip could also easily be added to any mug with a molded one piece plastic liner-rim construction. Furthermore, incorporating a clip into a stainless steel type of travel mug would be very inexpensive by providing the stainless steel mug body with an injection molded plastic liner-rim-handle-clip unitary construction. Assembly of such a mug could be quickly accomplished by connecting the plastic injection molded component with the stainless steel outer shell. The advantage is that a clip need not be separately and independently attached to a mug body. This simplifies construction and reduces the cost of making a mug with a clip. Finally, the clip could be incorporated during injection molding into other parts, for example a plastic rim, wherein the clip is not restricted to placement underneath the handle. Furthermore, a clip 200 could be integrally formed underneath any plastic mug handle, and the mug handle could then be attached to the outside of a variety of drinking containers in various ways well known in the art.

The mug body 300 may either have an integral mug base, or alternatively as in the preferred embodiment, the mug body 300 may include a separately attachable mug base 600, for example, comprised of rubber or plastic. As shown in FIG. 5, in the preferred embodiment, there are threads 710 on the bottom of the liner 700. The threads 710 on the bottom of the liner 700 screw into corresponding threads 610 on the mug base 600, securing the body 300 between the rim 400 and the base 600.

The present invention further includes a method of assembly of a drinking container with an article holding clip 200 comprising injection molding of a unitary construction including a liner 700, a rim 400, a handle 100, and a clip 200, and connecting said unitary construction with a mug body 300, preferably of stainless steel. The assembly may further include connecting the rim 400 with a lid 500, and connecting a mug base 600 with the mug body 300. In the preferred embodiment the method of assembly further includes securing the mug body 300 in between the rim 400 and the base 600 by screwing a mug base 600 with threads 610 onto corresponding threads 710 located on the bottom of the mug liner 700. This method makes the assembly of the unitary construction with the mug body 300 quick and inexpensive. No rivets, screws, bolts, welds, nor adhesives are required in the process of assembly.

Alternatively, another method could comprise injection molding of a unitary construction including a clip 200 and at least one other component chosen from the group consisting of a liner 700, a rim 400, or handle 100, and connecting said unitary construction with a mug body 300, preferably of stainless steel. This method also provides a quick and easy way to provide a clip that is biased against the body of a metal drinking container.

The present invention may be embodied in other specific forms without departing from the essential spirit or attributes thereof. It is desired that the embodiments described herein be considered in all respects as illustrative, not exhaustive or restrictive, and that reference be made to the appended claims for determining the scope of the invention.

1. A drinking container comprising:
a. an article holding clip connected to a drinking container handle.

2. A drinking container as in claim 1, wherein said clip is biased against a drinking container body.

3. A drinking container as in claim 1, wherein:
a. said clip is connected to the underside of said drinking container handle; and;
b. said clip is biased against a drinking container body.

4. A drinking container as in claim 1 further comprising:
a. a drinking container rim connected with said drinking container handle;
b. a drinking container liner connected with said drinking container rim; and;
c. a drinking container body connected with said rim, and said liner.

5. A drinking container as in claim 1 further comprising:
a. a drinking container rim connected with said drinking container handle;
b. a drinking container liner connected with said drinking container rim;
c. a drinking container body connected with said rim, and said liner; and;
d. a drinking container base connected with said liner and said body.

6. A unitary construction for use with a drinking container comprising:
a. a clip connected to, and integrated into, a drinking container handle wherein when said handle is connected with a drinking container body, said clip is biased against the drinking container body.

7. A unitary construction for use with a drinking container as in claim 6 wherein said clip is connected to the underside of said handle.

8. A unitary construction for use with a drinking container as in claim 6 further comprising a rim connected to, and integrated into, said unitary construction and connected with said drinking container handle.

9. A unitary construction for use with a drinking container as in claim 6 further comprising:
a. a rim, integrated into said unitary construction, and, connected with said drinking container handle; and;
b. a cup liner integrated into said unitary construction, and, connected with said rim.

10. A method of assembling a drinking container including an article holding clip comprising:
a. injection molding a unitary construction including a liner, a rim, a handle, and a clip; and;
b. connecting said unitary construction with a drinking container body.

11. A method of assembling a drinking container including an article holding clip as in claim 10 wherein said clip is integrated into the underside of the handle.

12. A method of assembling a drinking container as in claim 10:
a. wherein said drinking container body is connected with the unitary construction by connecting a base with the liner, securing the drinking container body therebetween.

13. A method of assembling a drinking container including an article holding clip as in claim 12 wherein connecting said unitary construction with the drinking container body comprises screwing a base onto corresponding threads on the bottom of the liner thereby securing the drinking container body between the rim and the base.

14. A method of assembling a drinking container as in claim 12:
a. further including connecting a detachable lid with the rim.

15. A method of assembling a drinking container including article holding clip comprising:
a. injection molding of a unitary construction including a clip and at least one other component chosen from the group consisting of a liner, a rim, and a handle; and;
b. connecting said unitary construction with a drinking container body.
